(19) United States
(12) Patent Application Publication
(10) Pub. No.: US 2026/0282520 A1
(43) Pub. Date: Sep. 17, 2026

(54) SEMICONDUCTOR DEVICE

(71) Applicant: Minebea Power Semiconductor Device Inc., Hitachi-shi, Ibaraki (JP)

(72) Inventors: Masaki NAMAI, Hitachi-shi (JP); Masaki SHIRAISHI, Hitachi-shi (JP)

(73) Assignee: Minebea Power Semiconductor Device Inc., Hitachi-shi, Ibaraki (JP)

(21) Appl. No.: 19/472,850

(22) PCT Filed: Jan. 31, 2024
(86) PCT No.: PCT/JP2024/002984

§ 371 Date: Oct. 6, 2025

(30) Foreign Application Priority Data
Apr. 12, 2023 (JP) 2023-064852

(51) Int. Cl. H10D 84/00; H10D 8/00; H10D 12/00; H10D 62/10; H10D 62/60

(52) U.S. Cl. CPC H10D 84/161; H10D 8/422; H10D 12/481; H10D 62/124; H10D 62/60

(57) ABSTRACT

A semiconductor device includes: a drift layer of a first conductivity type; a body layer of a second conductivity type formed in a surface layer on one principal surface side of the drift layer; a first diffusion layer of the first conductivity type partially formed in a surface layer on one principal surface side of the body layer; and a collector layer of the second conductivity type and a second diffusion layer of the first conductivity type having an impurity concentration higher than that in the drift layer, the collector layer and the second diffusion layer being formed in a surface layer on another principal surface side of the drift layer in a distributed manner.

### TECHNICAL FIELD

The present invention relates to a semiconductor device.

### BACKGROUND ART

As a technique related to a semiconductor device having an RC-IGBT configuration in which an insulated gate bipolar transistor (IGBT) and a free wheeling diode are provided in the same substrate, there is a technique disclosed in Patent Literature 1 mentioned below. This Patent Literature 1 discloses that, “In a semiconductor substrate, a guard ring of a second conductivity type to which a voltage having the same potential as that of an anode layer in a diode region is applied is formed in an outer peripheral region surrounding a device region in which an IGBT region and the diode region are formed. The cathode layer and the guard ring are formed at positions satisfying L/d≥1.5, where L represents the minimum value of the distance between the cathode layer and the guard ring when projected onto a plane parallel to a surface of the semiconductor substrate, and d represents the thickness of the semiconductor substrate. This prevents injection of a large amount of carriers from the guard ring into a drift layer, and can prevent a large amount of holes from flowing into the anode layer when the diode region is switched to the reverse bias. As a result, recovery tolerance of the diode can be further increased”.

### CITATION LIST

### Patent Literature

Patent Literature 1: JP 2017-224685 A

### SUMMARY OF INVENTION

### Technical Problem

Meanwhile, when the IGBT is turned on in the semiconductor device having the above-described configuration, conductivity modulation achieved by accumulating minority carriers in the IGBT region enables other operations to lower the on-resistance even with a high withstand voltage. In a turn-off operation of the IGBT, however, carriers accumulated in the IGBT region cause thermal breakdown of the device due to an increase in switching loss, and the reverse bias safe operating area (RBSOA) is narrowed.

Therefore, the present invention aims to provide a semiconductor device having an RC-IGBT configuration with which the reverse bias safe operating area (RBSOA) can be expanded.

### Solution to Problem

To solve the above problem, a configuration disclosed in the claims is adopted, for example.

The present application includes a plurality of means to solve the above problem, and one example of such a means is a semiconductor device that includes: a drift layer of a first conductivity type; a body layer of a second conductivity type formed in a surface layer on one principal surface side of the drift layer; a first diffusion layer of the first conductivity type partially formed in a surface layer on one principal surface side of the body layer; and a collector layer of the second conductivity type and a second diffusion layer of the first conductivity type having a higher impurity concentration than that in the drift layer, the collector layer and the second diffusion layer being formed in a surface layer on another principal surface side of the drift layer in a distributed manner. In the semiconductor device, a transistor region in which an IGBT element formed with the first diffusion layer, the body layer, the drift layer, and the collector layer is disposed, and a diode region in which an FWD element formed with the body layer, the drift layer, and the second diffusion layer is disposed are provided in the same semiconductor substrate. The diode region has a barrier layer of the first conductivity type between the body layer and the drift layer, the barrier layer having a higher impurity concentration than that in the drift layer. The area in which the body layer and the drift layer are in contact with each other is larger in a boundary region with the transistor region within the diode region than in the other region within the diode region.

### Advantageous Effects of Invention

According to the present invention, it is possible to provide a semiconductor device having an RC-IGBT configuration with which the reverse bias safe operating area (RBSOA) can be expanded.

### BRIEF DESCRIPTION OF DRAWINGS

FIG. 1 is a schematic cross-sectional view (part 1) of a semiconductor device according to a first embodiment.

FIG. 2 is a schematic cross-sectional view (part 2) of a semiconductor device according to the first embodiment.

FIG. 3 is a schematic cross-sectional view of a semiconductor device according to a second embodiment.

### DESCRIPTION OF EMBODIMENTS

In the following, embodiments to which the present invention is applied will be described in detail with reference to the drawings. Note that, in each of the embodiments described below, the same components are denoted by the same reference numerals, and explanation thereof will not be repeated. Although the first conductivity type is the n-type, and the second conductivity type is the p-type in the description below, the conductivity types may be reversed.

### First Embodiment

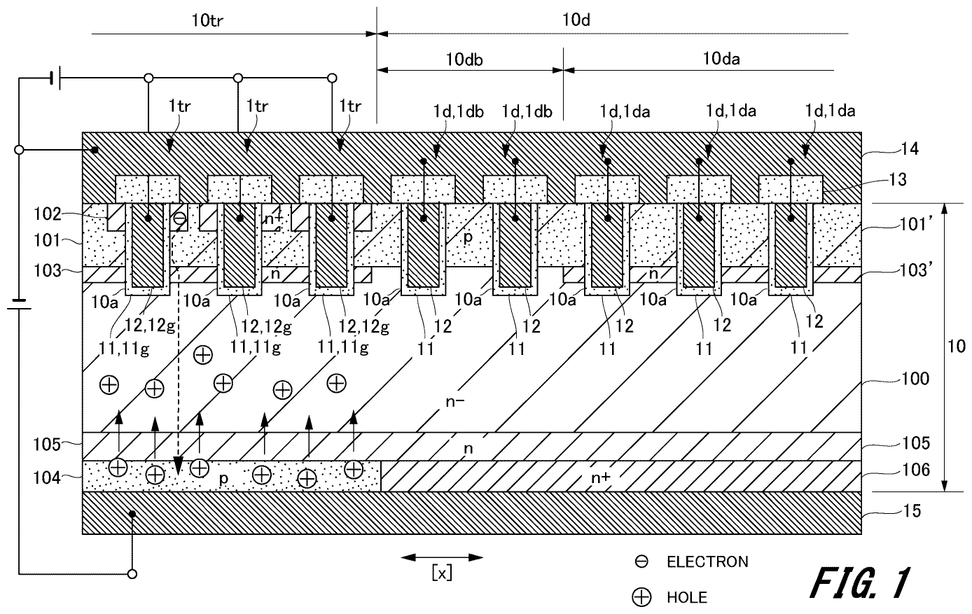

FIG. 1 is a schematic cross-sectional view (part 1) of a semiconductor device 1 according to a first embodiment. The semiconductor device 1 illustrated in this drawing is a reverse-conducting IGBT (RC-IGBT) in which insulated gate bipolar transistors (hereinafter referred to as the IGBT elements 1tr) and free wheeling diode (hereinafter referred to as the FWD elements 1d) are provided in the same semiconductor substrate 10. The following is a description of the semiconductor device 1, starting from a description of the region configuration in a case where the semiconductor substrate 10 is viewed in plan view, followed by a description of the cross-sectional configuration in a case where the semiconductor substrate 10 is viewed from a cross-section.

### Region Configuration

First, a region configuration of the semiconductor device 1 is described. The semiconductor substrate 10 in which the semiconductor device 1 is formed includes a transistor region 10tr in which a plurality of IGBT elements 1tr is disposed, and a diode region 10d in which a plurality of FWD elements 1d is disposed. Here, the transistor region 10tr and the diode region 10d are alternately arranged in an array direction [x], for example. However, the present invention is not limited to this, and the diode region 10d may be formed in an island-like shape and be disposed in the transistor region 10tr.

In the diode region 10d, the region adjacent to the transistor region 10tr is set as a boundary region 10db. Such a boundary region 10db is a region of about 100 μm from the boundary with the transistor region 10tr, and is a range in which a diffusion layer of the diode region 10d can affect the carriers in the transistor region 10tr as described below.

In such a boundary region 10db, boundary region FWD elements 1db having a different configuration from that of FWD elements 1da provided in another diode region 10da in the diode region 10d are provided. Hereinafter, in the diode region 10d including the boundary region 10db, the region other than the boundary region 10db will be referred to simply as the diode region 10da. Further, the FWD elements 1d provided in the diode region 10da other than the boundary region 10db will be referred to simply as the FWD elements 1da, as opposed to the boundary region FWD elements 1db.

FIG. 1 illustrates a cross-sectional structure in the array direction [x] across transistor region 10tr, the boundary region 10db, and the diode region 10da, and illustrates a cross-section of the IGBT elements 1tr of three elements, the boundary region FWD elements 1db of two elements, and the FWD elements 1da of three element portions.

Note that FIG. 1 illustrates an example in which two boundary region FWD elements 1db are arranged in the array direction [x] of the boundary region 10db, but the present invention is not limited to this. The number of the boundary region FWD elements 1db arranged in the array direction [x] may be one or more within the boundary region 10 db having a width of about 100 μm.

### Cross-Sectional Configuration

Next, a cross-sectional configuration of the semiconductor device 1 is described. The semiconductor substrate 10 in which the semiconductor device 1 is formed is a substrate that is of the first conductivity type and has a relatively low impurity concentration, and is an n-substrate herein. The semiconductor substrate 10 has a plurality of trenches 10a on the side of one principal surface (referred to as the front surface herein). Each of the trenches 10a extends in a direction (the depth direction in the drawing) perpendicular to the array direction [x], and is provided for each corresponding element, which is each IGBT element 1tr and each FWD element 1d, in the array direction [x]. These trenches 10a are formed in the same process, and may have the same depth.

Each trench 10a is filled with an electrode pattern 12 via an insulating film 11 provided on the inner wall of the trench 10a. The insulating film 11 may be formed on the inner wall of the trench 10a, or may be a film grown from the inner wall of the trench 10a into the semiconductor substrate 10 by oxidation or nitriding.

Among such insulating films 11, the insulating films 11 in the transistor region 10tr function as gate insulating films 11g. Further, among the electrode patterns 12, the electrode patterns 12 in the transistor region 10tr are used as gate electrodes 12g. On the other hand, the electrode patterns 12 in the diode region 10d are connected to an emitter electrode 14 described below.

On the surface of the semiconductor substrate 10, interlayer insulating films 13 are formed in such a pattern as to cover the electrode patterns 12. The interlayer insulating films 13 are patterned in a shape that covers the electrode patterns 12 and exposes the semiconductor substrate 10 between the trenches 10a. Furthermore, the emitter electrode 14 is patterned on one principal surface of the semiconductor substrate 10 via the interlayer insulating films 13. The emitter electrode 14 is maintained in a state insulated from the electrode patterns 12 in the trenches 10a by the interlayer insulating films 13, and is connected to the semiconductor substrate 10 between the interlayer insulating films 13.

On the other hand, a collector electrode 15 is patterned on the other principal surface (referred to as the back surface herein) of the semiconductor substrate 10.

Next, diffusion layer structures inside the semiconductor substrate 10 in the transistor region 10tr, the diode region 10da, and the boundary region 10db are described. Diffusion layers are layers that are formed by introducing an n-type impurity or a p-type impurity into the n-semiconductor substrate 10, and have the respective conductivity types. In the description below, the n-region in the semiconductor substrate 10 left by the formation of the diffusion layers by impurity introduction will be referred to particularly as an n-drift layer 100.

### Transistor Region 10tr

In the transistor region 10tr, the front surface side of the semiconductor substrate 10 in which the trenches 10a are provided is covered with a p-type diffusion layer (referred to as a p-type body layer 101). The p-type body layer 101 is formed at a position shallower than the trenches 10a described above.

On the front surface side of the p-type body layer 101, n+ diffusion layers 102 having such a width as to be exposed from the interlayer insulating films 13 are provided at positions in contact with the gate insulating films 11g. The n+ diffusion layers 102 are provided as n-type (first conductivity type) first diffusion layers. The n+ diffusion layers 102 have gaps between the adjacent trenches 10a, and the p-type body layer 101 is exposed through the front surface of the semiconductor substrate 10 at the gaps. With this configuration, the p-type body layer 101 and the n+ diffusion layers 102 are connected to the emitter electrode 14 at the portions between the trenches 10a.

Further, between the p-type body layer 101 and the n-drift layer 100, n-type barrier layers 103 formed with n-type diffusion layers having a higher n-type impurity concentration than the semiconductor substrate 10 are provided. The n-type barrier layers 103 are formed at positions shallower than the trenches 10a, and are disposed between the trenches 10a. Although the drawing shows a configuration in which the n-type barrier layers 103 are provided so as to close the portions between the trenches 10a, the n-type barrier layers 103 may be disposed at centers between the trenches 10a and may be provided at a distance from the gate insulating films 11g.

In the above configuration, a MOS transistor having the n+ diffusion layers 102 as the drain and the n-type barrier layers 103 and the n-drift layer 100 as the source is disposed on the front surface side of the semiconductor substrate 10 in the transistor region 10tr.

On the other hand, in the transistor region 10tr, the p-type collector layer 104 whose outermost surface is a p-type diffusion layer is provided on the back surface side of the semiconductor substrate 10. Further, in the semiconductor substrate 10, an n-type buffer layer 105 formed with an n-type diffusion layer is provided between the p-type collector layer 104 and the n-drift layer 100. Note that the n-type buffer layer 105 may be provided as necessary, and is not necessarily provided.

In the above configuration, a PNP bipolar transistor in which the n-type barrier layers 103, the n-drift layer 100, and the n-type buffer layer 105 are sandwiched between the p-type body layer 101 and the p-type collector layer 104 is disposed in the transistor region 10tr.

Further, in the transistor region 10tr, the IGBT elements 1tr using MOS transistors arranged on the front surface side of the semiconductor substrate 10 as the switching elements of the PNP bipolar transistor are disposed.

The IGBT elements 1tr enter a current conduction state by applying a positive voltage for the emitter electrode 14 to the gate electrodes 12g. In this case, electrons gather at a position along the gate electrodes 12g of the p-type body layer 101, and an n-type inverted channel is formed, so that a base current flows in the PNP bipolar transistor. Electrons supplied from the emitter electrode 14 reach the collector electrode 15 through the path formed with the n+ diffusion layers 102, the n-type channel, the n-type barrier layers 103, the n-drift layer 100, the n-type buffer layer 105, and the p-type collector layer 104. Holes supplied from the collector electrode 15 reach the emitter electrode 14 through a path that is the reverse of that for electrons.

In this case, as the n-type barrier layers 103 are provided, movement of holes from the n-drift layer 100 to the p-type body layer 101 is prevented, and holes can be effectively accumulated in the n-drift layer 100. As a result, a conductivity modulation effect of the IGBT elements 1tr is ensured, and an increase in on-resistance can be prevented.

### Diode Region 10da

In the diode region 10da, the front surface side of the semiconductor substrate 10 in which the trenches 10a are provided is covered with an anode layer 101′ formed with the p-type body layer 101. The anode layer 101′ is formed at a position shallower than the trenches 10a described above. Also, the anode layer 101′ is connected to the emitter electrode 14 at the portions between the trenches 10a.

Between the anode layer 101′ and the n-drift layer 100, n-type barrier layers 103′ formed with n-type diffusion layers having a higher n-type impurity concentration than the semiconductor substrate 10 are provided. The n-type barrier layers 103′ may have the same configuration as the n-type barrier layers 103 in the transistor region 10tr, and may be layers formed in the same process. Accordingly, the n-type barrier layers 103′ are formed at positions shallower than the trenches 10a, and are disposed between the trenches 10a. Also, the n-type barrier layers 103′ may be disposed at centers between the trenches 10a, and may be provided at distances from the insulating films 11 on the inner walls of the trenches 10a.

On the other hand, in the diode region 10d, a second diffusion layer of the first conductivity type (n-type) having a higher impurity concentration than the drift layer is provided as a cathode layer 106 on the back surface side of the semiconductor substrate 10. The back surface side of the semiconductor substrate 10 is covered with the cathode layer 106 formed with an n+ diffusion layer. The cathode layer 106 is provided in contact with the collector electrode 15, and is connected to the collector electrode 15. Such a cathode layer 106 may have the same depth as the p-type collector layer 104 in the transistor region 10tr, for example.

Further, the n-type buffer layer 105 formed with an n-type diffusion layer extending from the transistor region 10tr is provided between the cathode layer 106 and the n-drift layer 100. The n-type impurity concentration in the n-type buffer layer 105 is higher than that in the n-drift layer 100 and is lower than that in the cathode layer 106. Note that the n-type buffer layer 105 may be provided as necessary, and is not necessarily provided.

With the above configuration, in the diode region 10da, the anode layer 101′ is connected to the emitter electrode 14, and the cathode layer 106 is connected to the collector electrode 15, so that the FWD elements 1da connected in antiparallel to the IGBT elements 1tr disposed in the transistor region 10tr are disposed therein.

Since the FWD elements 1da are connected in antiparallel to the IGBT elements 1tr, a reverse bias is applied to the anode layer 101′ and the cathode layer 106, and any current does not flow therein in a state where the IGBT elements 1tr are in a conductive state. On the other hand, in a case where the IGBT elements 1tr are turned off from the conduction state, the FWD elements 1da serve as a path for releasing the free wheeling current generated in the turned-off IGBT elements 1tr, and thus, prevent damage to the IGBT elements 1tr.

Further, in a case where the FWD elements 1da are brought into a forward conductive state by the flow of the above free wheeling current, the n-type barrier layers 103′ provided in contact with the anode layer 101′ can prevent movement of holes from the anode layer 101′ to the n-drift layer 100.

### Boundary Region 10db

The diffusion layer structure of the semiconductor substrate 10 in the boundary region 10db differs from the diffusion layer structure in the diode region 10da only in that the n-type barrier layers 103′ are not provided. That is, the boundary region FWD elements 1db in the boundary region 10db have a configuration in which the n-type barrier layers 103′ are removed from the FWD elements 1da provided in the diode region 10da.

Since the boundary region FWD elements 1db are connected in antiparallel to the IGBT elements 1tr, a reverse bias is applied to the anode layer 101′ and the cathode layer 106, and any current does not flow therein in a state where the IGBT elements 1tr are in a conductive state. Further, in a case where the IGBT elements 1tr are turned off from the conduction state, the FWD elements 1d serve as a path for releasing the free wheeling current generated in the turned-off IGBT elements 1tr, and thus, prevent damage to the IGBT elements 1tr, like the FWD elements 1da do.

### Effects of First Embodiment

The semiconductor device 1 of the first embodiment described above has a configuration in which the n-type barrier layers 103′ are disposed only in the diode region 10da excluding the boundary region 10db. As a result, in the boundary region 10db, any region having a higher n-type impurity concentration than that in the n-drift layer 100 does not exist between the p-type anode layer 101′ and the n-drift layer 100, and the anode layer 101′ and the n-drift layer 100 are in contact with each other over a wide area. With such a configuration, the effects described below can be achieved.

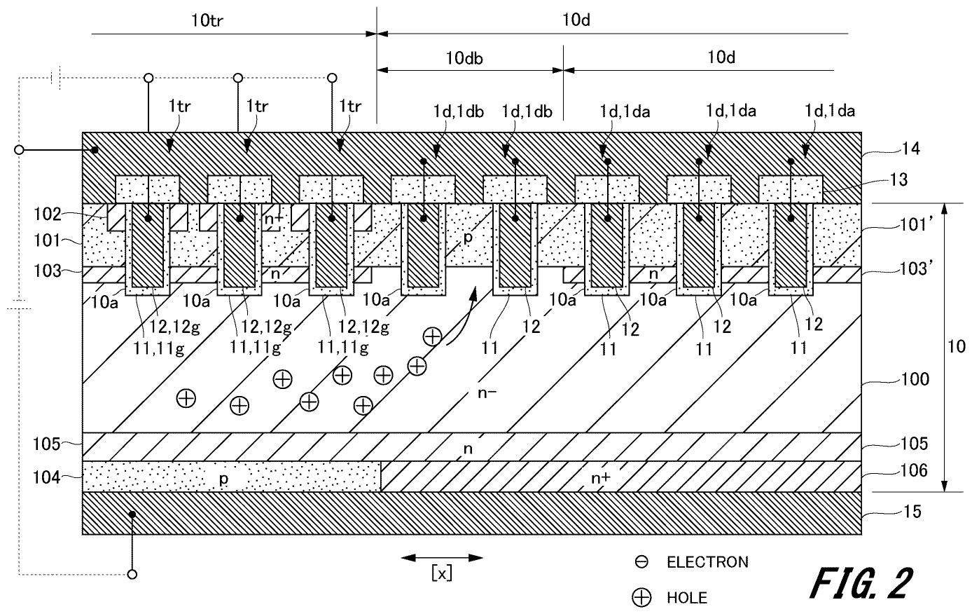

FIG. 2 is a schematic cross-sectional view (part 2) of the semiconductor device according to the first embodiment, and is a schematic view of the semiconductor device that is turned off when the IGBT elements 1tr are switched from a conduction state to an off-state. As illustrated in FIG. 2, in a state where the IGBT elements 1tr are turned off, holes as minority carriers are accumulated in the n-drift layer 100 in the transistor region 10tr. At this point of time, in the boundary region 1db, the n-type barrier layers 103′ having a high n-type impurity concentration do not exist, and the region p-type anode layer 101′ is exposed in that state. Therefore, holes in the n-drift layer 100 are easily discharged from the p-type anode layer 101′.

As a result, the total amount of carriers (holes) to be discharged by the dynamic avalanche at the junction between the p-type body layer 101 and the n-type barrier layers 103 of the turned-off IGBT elements 1tr can be reduced. The base current to be supplied to pnpn-type parasitic thyristors existing in the IGBT elements 1tr then decreases, and latch-up breakdown of the IGBT elements 1tr can be prevented. As a result, it is possible to expand the reverse bias safe operating area in the semiconductor device 1 having an RC-IGBT configuration.

Note that, in the first embodiment described above, the n-type barrier layers 103′ are not provided in the boundary region 10db. However, the boundary region 10db may have a configuration in which the area of contact between the anode layer 101′ and the n-drift layer 100 is made larger than that of the transistor region 1da by the n-type barrier layers 103′ having a shape smaller than that in the transistor region 1da. Even with such a configuration, it is possible to achieve an effect of expanding the reverse bias safe operating area as described above.

### Second Embodiment

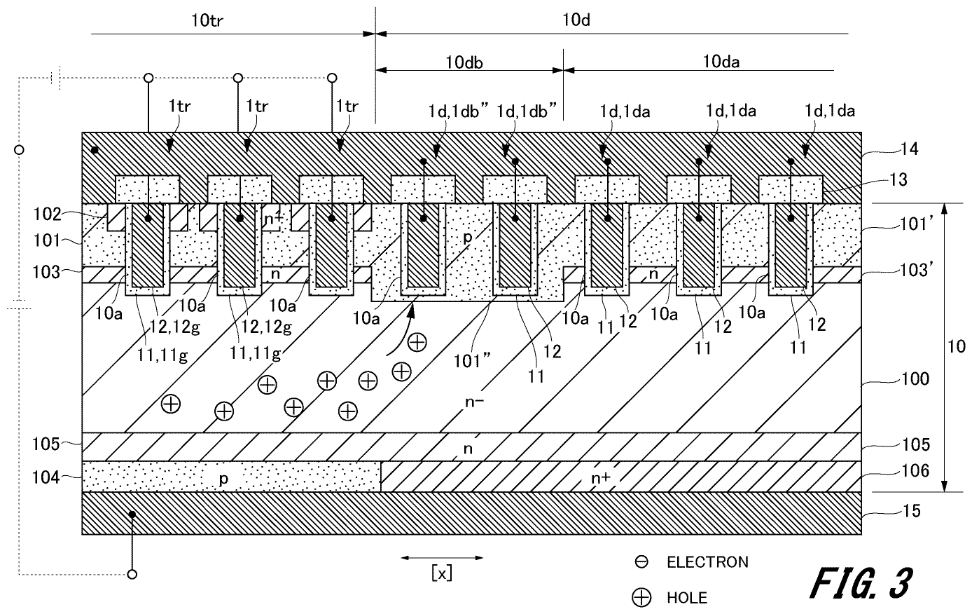

FIG. 3 is a schematic cross-sectional view of a semiconductor device 2 according to a second embodiment. The semiconductor device 2 of the second embodiment illustrated in this drawing differs from the semiconductor device 1 of the first embodiment described above with reference to FIGS. 1 and 2 in the depth of an anode layer 101″ of boundary region FWD elements 1db″ provided in the boundary region 10db, and other aspects are the same.

The anode layer 101″ of the boundary region FWD elements 1db″ is formed at a position deeper than the anode layer 101′ in the diode region 10da. The depth of the anode layer 101″ may be deeper than the anode layer 101′ in the diode region 10da, but is preferably also deeper than the trenches 10a.

Further, as illustrated in FIG. 3, the anode layer 101″ more preferably has such a shape as to cover the bottom surfaces of the trenches 10a. Such an anode layer 101″ can be formed by introducing a p-type impurity into the semiconductor substrate 10 to a depth greater than a predetermined formation depth of the trenches 10a before forming the trenches 10a. Note that, in a case where the insulating films 11 are grown from the inner walls of the trenches 10a into the semiconductor substrate 10 by oxidation or nitriding, the anode layer 101″ is formed at a depth, with the thickness of the insulating films 11 being taken into consideration.

### Effects of Second Embodiment

In the semiconductor device 2 of the second embodiment as described above, the anode layer 101″ in the boundary region 10db is deeper than the anode layer 101′ in the diode region 10da. Accordingly, the interface between the p-type anode layer 101″ and the n-drift layer 100 in the boundary region 10db is closer to the n-drift layer 100 in the transistor region 10tr than in the configuration of the first embodiment. Thus, during a turn-off operation of the IGBT elements 1tr, the holes accumulated in the n-drift layer 100 are more easily discharged from the anode layer 101″ in the boundary region 10db than in the configuration of the first embodiment.

Further, as the shape of the anode layer 101″ in the boundary region 10db is such a shape as to cover the bottom surfaces of the trenches 10a, the interface between the p-type anode layer 101″ and the n-drift layer 100 in the boundary region 10 db is made larger. Thus, the effect of discharging holes from the n-drift layer 100 at a time of a turn-off operation can be achieved more effectively.

Although the first conductivity type is the n-type while the second conductivity type is the p-type in each of the above-described embodiments, the conductivity types may be reversed. In this case, in the description of each embodiment, the n-type may be replaced with the p-type, the p-type may be replaced with the n-type, the anode may be replaced with the cathode, electrons may be replaced with holes, and holes may be replaced with electrons.

Note that the present invention is not limited to the above-described embodiments and modifications, and further includes various modifications. For example, the above-described embodiments have been described in detail for easy understanding of the present invention, and are not necessarily limited to those including all the described components. Also, one of the components of an embodiment can be replaced with a component of some other embodiment, and a component of an embodiment can be added to the components of some other embodiment.

Further, it is possible to add, delete, or replace one of the components of each embodiment to, from, or with some other component.

### REFERENCE SIGNS LIST

1, 2 Semiconductor device
1tr IGBT element
1d FWD element
1db, 1db″ Boundary region FWD element
10 Semiconductor substrate
10a Trench
10bd Boundary region
10tr Transistor region
10d Diode region
11 Insulating film
12 Electrode pattern
100 n-drift layer
101 p-type body layer
101′, 101″ Anode layer (p-type body layer)
102 n+ diffusion layer (first diffusion layer of first conductivity type)
103, 103′ n-type barrier layer
104 p-type collector layer
106 Cathode layer (second diffusion layer of first conductivity type)

1. A semiconductor device comprising:
a drift layer of a first conductivity type;
a body layer of a second conductivity type formed in a surface layer on one principal surface side of the drift layer;
a first diffusion layer of the first conductivity type partially formed in a surface layer on one principal surface side of the body layer; and
a collector layer of the second conductivity type and a second diffusion layer of the first conductivity type having a higher impurity concentration than an impurity concentration in the drift layer, the collector layer and the second diffusion layer being formed in a surface layer on another principal surface side of the drift layer in a distributed manner,
the semiconductor device having a transistor region in which an IGBT element formed with the first diffusion layer, the body layer, the drift layer, and the collector layer is disposed, and a diode region in which an FWD element formed with the body layer, the drift layer, and the second diffusion layer is disposed, the transistor region and the diode region being provided in an identical semiconductor substrate, wherein
the diode region has a barrier layer of the first conductivity type between the body layer and the drift layer, the barrier layer having a higher impurity concentration than the impurity concentration in the drift layer, and
an area in which the body layer and the drift layer are in contact with each other is larger in a boundary region with the transistor region within the diode region than in another region within the diode region.

2. The semiconductor device according to claim 1, wherein,
in the diode region, the barrier layer is provided only in a region other than the boundary region.

3. The semiconductor device according to claim 1, wherein
the boundary region is a region in a range of up to 100 μm from the transistor region.

4. The semiconductor device according to claim 1, wherein
the transistor region has the barrier layer between the body layer and the drift layer.

5. The semiconductor device according to claim 1, wherein
a depth of the body layer is greater in the boundary region than in another region.

6. The semiconductor device according to claim 1, further comprising:
a trench; and an electrode pattern buried in the trench via an insulating film on one principal surface side of the semiconductor substrate, wherein
a depth of the body layer is greater than a depth of the trench in the boundary region, and is smaller than the depth of the trench in another region.

7. The semiconductor device according to claim 6, wherein
the body layer is provided to cover a bottom surface of the trench in the boundary region.

8. The semiconductor device according to claim 6, wherein
the first diffusion layer is provided in contact with the insulating film in the trench in the transistor region, and
the barrier layer is disposed between the trenches.
